(19) United States
(12) Patent Application Publication
(10) Pub. No.: US 2010/0254067 A1
(43) Pub. Date: Oct. 7, 2010

(54) Method of making electronic ceramic components with mesh electrode

(76) Inventor: Frank Wei, Valencia, CA (US)

Correspondence Address: Frank Wei, 26135 Quartz Mesa Lane, Valencia, CA, 91381, US

(21) Appl. No.: 12/384,398

(22) Filed: Apr. 4, 2009

(51) Int. Cl. H01G 4/12; H01G 2/08; B05D 5/12; B32B 37/00; C25D 13/00; C23C 14/24; C23C 14/46; C23C 14/38

(52) U.S. Cl. 361/274.2; 361/321.1; 361/321.2; 361/321.5; 427/79; 156/60; 204/471; 427/81; 427/523; 204/192.17

(57) ABSTRACT

A method of manufacturing electronic ceramic components, especially multilayer ceramic components, by applying a green ceramic layer through chemical coating methods on a mesh electrode of at least one sheet of conductive mesh to achieve extended ceramic layer thickness range, improved thermal conductivity, and improved mechanical strength of the components. The green ceramic coated mesh electrode can be wound up into a cylindrical format or stacked up into a multilayer format, then sintered into a multilayer component body. A counter electrode of an impregnated conductive substance or a deposited conductive layer is formed on the top of sintered ceramic layer separately with the sintering of the ceramic active layer to eliminate the internal stresses caused by conventional co-firing process.

### CROSS-REFERENCE TO RELATED APPLICATIONS

U.S. patent documents

| | | | |
|---|---|---|---|
| 2,582,993 | January 1952 | Howatt | 25/156 |
| 2,779,975 | January 1955 | Lee | 18/47.5 |
| 3,189,978 | June 1965 | Stetson et al. | 29/155.5 |
| 3,232,856 | February 1966 | Klach et al. | 204/181 |
| 3,330,697 | August 1963 | Pechini | 117/215 |
| 3,604,082 | September 1971 | McBrayer et al. | 156/89 |
| 3,909,327 | September 1975 | Pechini | 156/89 |
| 4,324,750 | April 1982 | Maher | 264/61 |
| 4,697,001 | October 1986 | Walker et al. | 528/423 |
| 4,910,638 | March 1990 | Berghout et al. | 361/321 |
| 5,023,208 | December 1989 | Pope et al. | 501/12 |
| 5,116,643 | May 1992 | Miller et al. | 427/126.3 |
| 5,198,269 | August 1989 | Swartz et al. | 427/226 |
| 5,369,390 | November 1994 | Lin et al. | 338/21 |
| 5,495,386 | August 1993 | Kulkarni | 361/303 |
| 5,500,996 | March 1996 | Fritsch et al. | 29/612 |
| 5,812,367 | April 1997 | Kudoh et al. | 361/523 |
| 6,160,472 | December 2000 | Arashi et al. | 338/21 |
| 6,942,901B1 | September 2005 | Tassel et al. | 427/458 |
| 7,042,707B2 | May 2006 | Umeda et al. | 361/321 |

### BACKGROUND OF THE INVENTION

1. Field of the Invention

The present invention relates to electronic ceramic components and to the method of making the same. More specifically, the present invention relates to the electronic ceramic components which have a basic functional structure of a ceramic active layer coated on a conductive mesh electrode with a top counter electrode. The ceramic coated mesh electrode can be further wound or stacked up into multilayer type electronic ceramic components.

2. Description of the Prior Art

Electronic ceramic components, based on their electrode configuration, can be divided into two categories: 1) one electrode in each component, which allows an electrical current to pass through the component, such as multilayer chip inductor, ceramic heating element, and feed through filter; 2) two electrodes with a ceramic active layer interposed between, which allows an electrical voltage to apply across the ceramic active layer, such as multilayer ceramic capacitor (MLCC), chip varistor, and thermistor sensor. In such a two electrodes structured component, the active layer thickness and the active area are variables controlled through the manufacturing process to meet designed functionality of the component. For example, the capacitance value of a ceramic capacitor is determined by the formulation C=KεA/h (J. M. Herbert, “Ceramic Dielectrics and Capacitors”, Gordon and Breach Science Publishers, 1992. P9), where the “K” is the dielectric constant, “ε” is the dielectric constant of vacuum, “A” is the ceramic active area between two electrodes, and “h” is the thickness of the active layer between the two electrodes. Therefore, the capacitance value is proportional to the active area, and inversely proportional to the thickness of the active layer. Such two-electrode structured electronic ceramic components are often built into stacked multilayer formats for the purpose to improve the volumetric efficiency of the components. For example, a multilayer chip varistor has an improved surge resistance (U.S. Pat. No. 6,160,472), and a multilayer ceramic thermistor has a broad range of resistance independent of its dimensions (U.S. Pat. No. 5,500,996).

To make a comminuted ceramics powder into a sheet-like ceramic tape to be used as the active layer of a ceramic component, a tape casting process, disclosed by Howaft in U.S. Pat. No. 2,582,993 in 1952, has been most widely used for the mass production of electronic ceramic components. The comminuted ceramic powder is first dispersed into a binder solution, creating a viscous ceramic slip. The slip is then forced to flow through a narrow nozzle between a slip hopper and a flat moving carrier to form an even slip coating on the surface of the moving carrier. As the slip coating further moves into a dry oven, evaporating the solvent, it becomes a green (unfired) ceramic tape. The thickness of the green ceramic tape is controlled by adjusting the nozzle space between the hopper and the moving carrier, normally in the range of a few micrometers to several hundred micrometers.

To make a ceramic green tape into a functional ceramic component, additional elements, especially electrodes, are necessary. Several methods of depositing electrodes on ceramic green tape were patented and widely used in the electronic ceramic industry. P. W. Lee disclosed a method to make a multilayer electrical unit by depositing liquid vehicles containing metal particles in U.S. Pat. No. 2,779,975 in 1955. McBrayer et al. disclosed a method to stack green ceramic sheets alternatively with metal electrode layers and sintering them together (so called “co-fire”) to make a monolithic multilayer capacitor in U.S. Pat. No. 3,604,082. When ceramic active layer and metal electrode are co-fired, the two materials, with one shrinking more than the other, are sintered together. Internal stresses are induced within the multilayer structure due to the shrinkage mismatch, which becomes the root cause response for the component structural defects such as delaminations or micro-cracks. Numerous methods, such as adding ceramic powder into metal electrode paste, pre-coating metal particles with a ceramics, or adding ceramic interleaf layers during the stacking process have been used to control the shrinkage mismatch between the ceramic layer and metal electrode layer. However, to follow the miniaturization trend of electronic devices and meet the requirements for higher performances, multilayer electronic components manufactured through conventional production methods of tape casting for ceramic active layer and screen printing for metal electrode layer are challenged for higher and higher integration, which means more layer counts, thinner layer thickness, are integrated in smaller case sizes. This makes the shrinkage mismatch control increasingly difficult.

In an attempt to reduce ceramic layer thickness beyond the capability of tape casting method, sol gel technology has been intensively studied as a low cost ceramic thin film process since Pechini disclosed the sol gel process to make formulated dielectrics into a capacitor in his U.S. Pat. No. 3,330,697 in 1963. The sol gel process is particularly suited for the preparation of ceramic thin films and coatings in the thickness of submicron level. Almost any crystalline or amorphous film or coating can be applied to a variety of substrates through the sol gel process. Numerous methods with improved sol gel formulation and film quality have been invented and disclosed. Pope et al. disclosed a crack-free sol gel process by heating gel monoliths in an autoclave in U.S. Pat. No. 5,023,208. Miller et al. disclosed an improved sol gel process by hydrolyzing sol solution under an inert atmosphere to form thin film of PZT family ferroelectrics in U.S. Pat. No. 5,116,643. However, there are still many unresolved issues involved in making a thin, crack-free ceramic coating, especially on a large area of a flat surface substrate for mass production.

Compared to sol gel method, Electrophoretic deposition (EPD) method is particularly useful for applying a uniform coating in a high deposition rate on the surface of an electrically conductive complex object. Non-conductive colloidal particles which carry a charge in a stable suspension solution such as polymers, ceramics, and metal oxides can be formed into a dense coating through the EPD method. Van Tassel et al. disclosed a method in U.S. Patent Application No. 6,942,901 B1 for making a single or multiple layer component, which does not remove a deposition from the moving carrier until a single layer or multilayer structure is built up on the moving carrier through the EPD method. This provided a method for overcoming the difficulty of handling each individual layer. However, as long as a stack of multiple layer of ceramic and metal electrode is co-fired, the internal stress caused by shrinkage mismatch still exists.

On the other hand, due to the fragile nature of sintered ceramics body and a high volume ratio of ceramics to metal, electronic ceramic components, especially multilayer ceramic components, have low mechanical strength and poor thermal conductivity. This also explains the reason why most electronic ceramic components are made into small case sizes suitable for surface mount applications. Even though, when subjected to thermal and mechanical stresses during the soldering process as well as the printed circuit board assembling process, thermal shock and mechanical crack of ceramic components still possess the majority of on-board failures.

### BRIEF SUMMARY OF THE INVENTION

The present invention provides a method of manufacturing electronic ceramic components by coating a green ceramic layer on a mesh electrode of at least one sheet of conductive mesh and depositing a conductive layer on the top of sintered ceramic layer as the counter electrode. The green ceramic coated mesh electrode can be wound up into a cylindrical format or stacked up into a multilayer format, sintered into a multilayer component body, and impregnated with conductive substance to become a multilayer ceramic component.

According to one embodiment of the invention, there is provided a method to make ceramic capacitors comprising of a coated green ceramic layer which partially covers the surface of a mesh electrode of at least one sheet of conductive mesh substrate. Green ceramic coated conductive meshes are wound or stacked up to form a multilayer format and further sintered into a multilayer component body with interconnected ceramic channels through the mesh lattices. A counter electrode is further formed by impregnating an electrically conductive substance into the interconnected channels. Ceramic capacitor component based on this embodiment is able to reach high volumetric capacitance efficiency, or can be constructed into large size formats.

According to another embodiment of the invention, there is provided a method to make ceramic capacitors comprising of a coated green ceramic layer which partially covers the surface of a mesh electrode of at least one sheet of conductive mesh substrate. After sintering the green ceramic layer into a dielectric active layer, a layer of a conductive material is deposited on the top of the ceramic dielectric layer as a counter electrode to form a single layer capacitor with a sandwich structure of one ceramic active layer interposed between two electrodes. Plurality of the single layer capacitors can be further stacked up into a multilayer format such that a high volumetric capacitance and a large size format can be reached.

According to still another embodiment of the invention, there is provided a single layer ceramic varistor comprising of a ZnO layer coated on a conductive mesh electrode of at least one layer of mesh substrate and a counter electrode deposited on the top of the sintered ZnO active layer. Stacking plurality of the single layer ceramic varistor into a multilayer structure creates a multilayer ceramic varisor that is reinforced with grouped mesh electrodes with advanced thermal shock resistance. Similarly, by coating a ceramic formulation with temperature coefficient of linear voltage change, the same method applies to the manufacture of ceramic thermistor as well.

One significant advantage of this invention over the related prior art is that an extended active layer thickness range, from sub-microns to hundreds microns, is achievable by coating a ceramic solution on a mesh substrate through chemical coating methods. Another advantage of this invention over the related prior art is the improved mechanical strength and thermal shock resistance, especially for the multilayered ceramic components made in accordance with this invention, which is cored and reinforced by an electrically as well as thermally conductive mesh. Still another advantage of this invention over the related prior art is the elimination of internal stresses of a multilayer ceramic component by avoiding the co-firing of ceramic layer with metal electrode layer.

### BRIEF DESCRIPTION OF THE DRAWINGS

FIG. 1 shows a schematic view of ceramic active layer 11 coated on the surface of a conductive mesh 12 with a deposited counter electrode layer 13.

FIG. 2 shows a process flow chart to make a wound or stacked multilayer electronic ceramic component.

FIG. 3 shows a schematic view of the cross section of a stacked multilayer ceramic component with conductive mesh electrode 31, coated ceramic active layer 32, and counter electrode 33.

FIG. 4 shows a schematic view of the cross section of a wound type ceramic component with conductive mesh electrode 41, coated ceramic layer 42, and impregnated electrolysis electrode 43.

FIG. 5 shows a schematic view of a multiple components assembly with a circulation of coolant passing through the mesh electrode lattice openings.

### DETAILED DESCRIPTION OF THE INVENTION

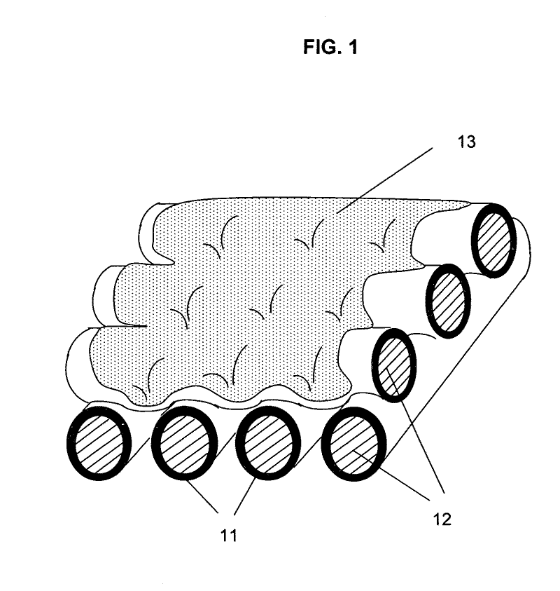

In reference to the illustrative drawings, and particularly to FIG. 1, there is depicted a representative structure of a ceramic active layer 11 coated on the surface of a conductive mesh substrate 12, and a counter electrode 13 deposited on the top of the ceramic active layer. The conductive mesh, by means, has a reticulated lattice shape made from electrically conductive materials. Numerous type of conductive meshes are commercially available and made through the processes of wire weaving, chemically etching or plating, mechanically stretching or punching, or particles sintering. Benefiting from recent developments of nano-technology, conductive mesh made from metal, carbon, or conductive polymers are available in thickness as thin as microns or sub-microns. The mesh thickness together with the mesh open ratio (defined as the total mesh open area to the total mesh size) determines the mesh usage. A thin mesh with low open ratio is desirable for thin ceramic coating for a component with high volumetric efficiency working at a low voltage. A thick mesh with high open ratio is suitable for making components with thick ceramic active layer for high voltage or high current applications. A conductive mesh can be made from electrically conductive materials including transition metals, semiconductors, or other materials with low resistivity. The transition metals include, but not limited to base metals such as nickel, cobalt, iron, tungsten, tantalum, molybdenum, copper, aluminum, and titanium, or noble metals such as silver, gold, palladium, platinum, or the combination of any of these base metals and noble metals and their alloys. The semiconductors include those in the carbon and graphite family and conductive oxides. The conductive meshes must have a melting point higher than the sintering temperature of the ceramic active layer coated on the meshes.

There are numerous advantages in using a mesh instead of a flat surface sheet as a coating substrate as well as an internal electrode for electronic ceramic components:
1) A mesh has higher surface area than a sheet with the same thickness. A wire woven mesh with 25% open area may have three times or more surface area than a sheet, depending on the woven method.
2) A mesh substrate can be covered more evenly with a coating solution than a flat surface substrate due to the existing of the surface tension of the coating solution. The surface tension of a liquid has a function of keeping the liquid in a spherical shape with the smallest surface area, such as a water droplet on a flat glass plate. When coated on a flat surface substrate, a coated ceramic solution, driven by the surface tension, has a tendency to shrink together and become uneven in thickness until being dried into a solid ceramic layer. In the case of a mesh type substrate, however, the surface tension drives the coating solution to penetrate through the mesh lattices to interconnect with the ceramic layers coated on the both sides of the mesh so that the whole mesh surface is covered evenly.
3) A sheet like mesh enables non-destructive surface inspection of the ceramic coating quality from both sides.
4) A liquid coolant or forced air is able to go through the openings of the mesh lattices to cool down the ceramic component efficiently.
5) Because most electrically conductive materials are also thermally conductive materials, ceramic components with a mesh cored ceramic active layer have higher metal to ceramic ratio, better thermal conductivity, and pliable mechanical strength.

According to present invention, there is provided a chemical coating method to make a liquid ceramic precursor into a uniform dense ceramic coating with controlled thickness onto the mesh substrate. A chemical coating process can be selected from sol gel process, coprecipitation process, EPD process, or metal-organic chemical vapor deposition (MOCVD) process. Ceramic dopands and glass frits (like those based on Bi₂O₃, CuO₂, CaO, B₂O₃, Li₂O or the combination of more than one of these oxides) can be used as partial precursor of the ceramic formulation, or be coated as an extra layer to the conductive mesh for the purpose to reduce the ceramic sintering temperature, or to improve the sintered ceramic density.

The first step of a sol gel coating process is to prepare a ceramic precursor, the sol solution containing organic metal alkoxides, metal salt solutions, or other metal complexes solutions in designed concentration and mole ratio. In order to obtain a sol solution capable of producing a ceramic layer with a required functional structure, precise control of the mole ratio of organic metals and extensive refluxing of the organic metal precursor are necessary. Metal organic sol solution can be made to react with water through hydrolysis and condensation steps to enhance the viscosity, therefore yielding a thicker ceramic layer per coating. A green ceramic layer is coated on the substrate by applying the sol solution on the surface of the substrate followed with a drying procedure to evaporate the solvent of the sol solution. The thickness of the coating is determined by the sol gel solution concentration, viscosity, and coating method such as dipping or spin coating. A certain coating thickness can be reached by repeating the coating and drying procedures. Coated ceramic layers have to be sintered to become a functional active layer. Different ceramic compositions need to be sintered at different temperature or under a controlled atmosphere to obtain desired ceramic functionality.

The MOCVD method is useful when depositing the vapor of a metal organic precursor through a carrier gas delivery system, enabling a deep penetration of the coating precursor through the mesh substrate. Although the deposition rate is relatively slow compared to other liquid coating method, more than one layer of the conductive mesh may be stacked up and coated at a time.

The EPD process is a preferred method for making thicker and denser green ceramic coatings. Most pre-formulated ceramic powder such as barium calcium zirconate titanate, lead magnesium niobate, barium titanate, magnesium niobate, or lead lanthanum zirconate titanate are insulated particles. When dispersed in an aqueous solution, those pre-formulated ceramic particles will be easily charged positively or negatively through the adjustment of the aqueous solution pH. Therefore the ceramic particles can be selectively deposited on the conductive mesh which is submerged in the suspension solution in an EPD bath tank. The depositing rate is a function of the dc bias voltage and the concentration of the suspension solution.

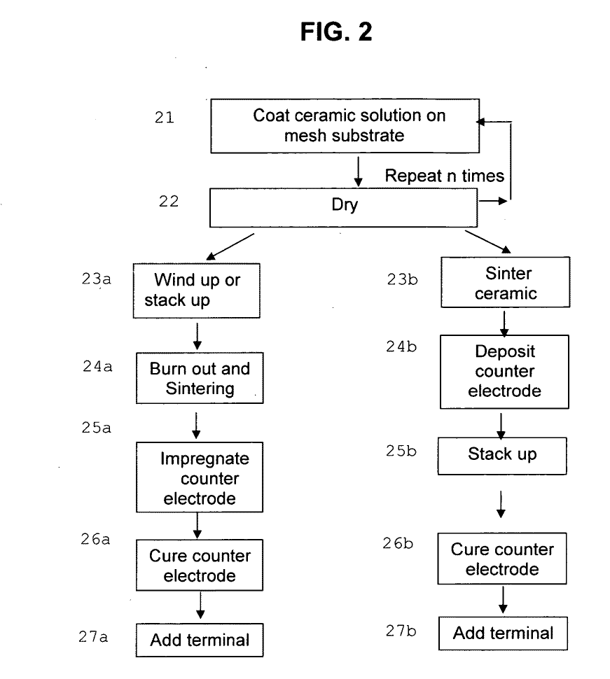

According to present invention, there is further provided a method to eliminate the ceramic component internal stresses by sintering ceramic active layer separately with the sintering of a counter electrode. The process flow chart of FIG. 2 displays two representative process routes to demonstrate how to make a ceramic component without co-firing the ceramic active layer with electrodes. Pre-diced mesh substrate in the shape of strips or rectangular chips are coated with ceramic solution in step 21. One end of each pre-shaped mesh piece is left uncovered by the ceramic coating where will be connected to one terminal of finished component at process step 26a or 26b. The coating thickness is controlled through the ceramic solution viscosity or coating parameters, such as dipping speed for sol-solution coating or bias voltage for EPD. A drying process 22 follows every coating step 21 to evaporate the solvent away from the coated layer. Coating and drying processes are repeated for the purpose of obtaining an even thickness and crack-free coating quality, or reaching a designed ceramic coating thickness. Applying a ceramic layer on the mesh electrode through a slip coating method is an alternative process to coat a pre-formulated ceramic powder as a thicker ceramic layer on a mesh with large openings.

After dried, but before sintered, a green ceramic coated mesh can be easily wound up into a cylindrical format if it was pre-diced in a strip shape, or easily stacked up into a multilayer format if it was pre-diced in a small chip size pieces at step 23a. Thereafter, at step 24a the cylindrical or multilayer formats of the green ceramic coated mesh will go through a burn out process at a temperature high enough to thermally decompose the organic substance, and then be sintered into a functional ceramic active layer. There are numerous ceramic contacting spots between any two spirals of wound mesh or any two layers of stacked mesh chips, which will be sintered together by undergoing sintering process 24a to become interconnected ceramic channels throughout the mesh lattices.

At the next step 25a the sintered cylindrical or multilayer formats will be impregnated with a liquid substance such as a MnNO₃ electrolytic solution used in example 2. The impregnated MnNO₃ solution filled into the interconnected channels will be heat treated to 550° C. at step 26a to become a conductive MnO₂ layer covering the ceramic active layer as a counter electrode. A conductive polymer such as polypyrrole disclosed in U.S. Pat. No. 5,812,367 by Kudoh et al. works in the same way as MnO₂ counter electrode does:

At the next step of 27a, one end of the wound or stacked multilayer formats which is uncovered by the ceramic coated layer will be terminated with a conductive silver paste to form a terminal of the component. The opponent terminal is subsequently formed by applying the same silver paste at the opposite end electrically connected to the MnO₂ counter electrode. Lead wires will be attached to the terminals if to make the component into a wire leaded one. Both wound and stacked components need to be packed with protective packages.

As also shown in flow chart FIG. 2, there is an alternative process route to make a multilayer ceramic component without co-firing ceramic active layer with the metal electrodes. Following the repeated process step 21 and 22, the ceramic coated mesh substrate is sintered at step 23b instead of being stacked at step 23a. Thereafter, a counter electrode is deposited on the top of sintered ceramic active layer at step 24b. So far a basic functional unit of a ceramic active layer interposed between two electrodes has been made. Plurality of such basic functional units are then stacked up at process step 25b. The counter electrode layer can be selected from conductive materials such as metals, semiconductors, or conductive polymers which have a melting point lower than the sintering temperature of the ceramic active layer. The conductive counter electrode can be deposited by either a chemical method (such as electroless plating, dip coating, or EPD) or a physical method (such as vacuum deposition, plasma sputtering, or laser ablation). A process to coat indium tin oxide (ITO) sol gel solution and sintering the ITO coating into a counter electrode is demonstrated in Example 1. Thus stacked mesh pieces, with numerous contacting spots between any two coated counter electrodes, are further heat treated at step 26b at a temperature high enough to make the contacting spots jointed together to form a multilayer component body. At the next step 27b the two ends of thus constructed multilayer format will be terminated with silver paste to form two terminals electrically connected to the mesh electrode or counter electrode respectively.

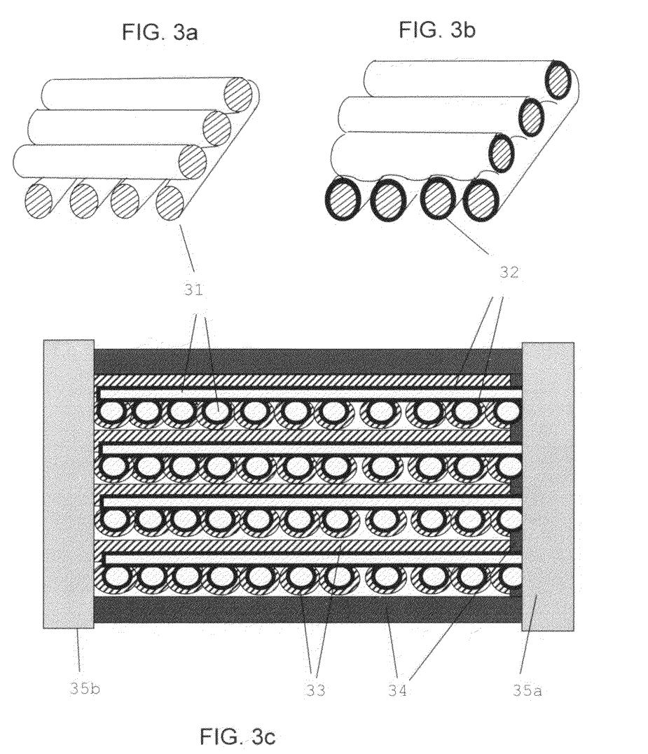

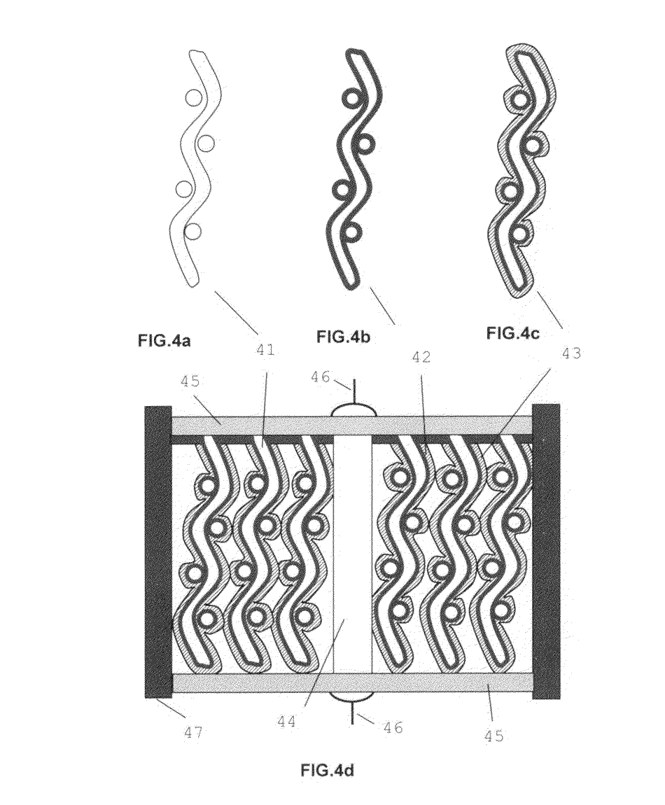

Flow chart FIG. 2 as well as FIG. 3 and FIG. 4 of schematic views of multilayer ceramic components are created for the purpose of illustrating the principles of the invention and should not be taken in a limiting sense. For example, a multilayer component body made at step 24a needs to be terminated and packed in a container before step 25a of the impregnation of counter electrode if the impregnated electrode needs to be kept in its liquid form as a wet counter electrode. It is also possible to make a multilayer ceramic component by exchanging the process step 24b with 25b to stack up sintered mesh pieces before depositing counter electrode on them if there are only a few layers in a stack.

### EXAMPLES

### Example 1

A surface mount type multilayer ceramic capacitor comprising of BaTiO₃ sol gel coated silver mesh with ITO thin film counter electrode is depicted as FIG. 3 for an easy understanding of the process.

Mix 0.2 mol/L barium isopropoxide Ba(OC₃H₇)₂ solution (Chemat, US) with 0.2 mol/L titanium amyloxide Ti(OC₅H,₁)₄ solution (Aldrich, US) and reflux the mixture at 80° C. overnight to obtain a 0.2 mol/L BaTiO₃ stock solution. A 20 μm thick silver mesh 31 made by cross-overlapping 10 μm diameter silver rods is used as the coating substrate as shown in FIG. 3a. The mesh 31 has a surface area of 0.29 square meters per cubic centimeter with 25% opening ratio. The silver mesh is diced into 6.4 mm×1.6 mm rectangular chip pieces and dipped in the BaTiO₃ sol stock solution followed by a quick drying at 150° C. for 30 seconds to obtain a 0.1 μm thick green BaTiO₃ coating. Repeat the dipping and drying process three times to reach a 0.3 μm thick green BaTiO₃ coating which will be subsequently sintered at 930° C. for 3 hours to become a 0.2 μm dense BaTiO₃ dielectric layer 32 as shown in FIG. 3b and FIG. 3c.

The next step is to prepare an ITO sol gel solution by refluxing Indium isopropoxide (In(OC₃H7i)₃) (Chemat) and Tin (IV) isopropoxide (Sn(OC₃H7i)₄) (Chemat) together to obtain an ITO sol solution. The ITO sol solution is further diluted with isopropylalcohol and hydrolyzed with water into a 0.1 mol/L gel solution. Dip the previously prepared BaTiO₃ coated 6.4 mm×1.6 mm size rectangular mesh pieces in the 0.1 mol/L ITO gel solution and dry them at 80° C. for 5 minutes to obtain a uniform 0.1 μm thick ITO coating 33 on the top of BaTiO₃ dielectric active layer 32. Thereafter, 80 pieces of ITO coated rectangular pieces are stacked into a 1.6 mm thick rectangular cuboids multilayer block, annealed up to 550° C. in nitrogen atmosphere to make the top ITO coating 33 conductive. Meanwhile the 80 pieces are jointed together into one rigid component body. Each component body is diced in the middle of the longest side into two 1206 case size (3.2 mm×1.6 mm×1.6 mm) multilayer BaTiO₃ capacitor components with exposed silver mesh at one end. At the very end of exposed silver mesh it needs to be sealed with a conforming epoxy 34 and consequently terminated with a thermoset type conductive silver paste to form one capacitor terminal 35a. The opposite end can be similarly terminated as terminal 35b which is electrically connected to the ITO counter electrode 33. The remaining four sides of each 1206 case size capacitor component (except the two ends) are sealed with thermoset epoxy 34 to become a finished surface mount type MLCC component.

### Example 2

A high voltage ceramic capacitor comprising of EPD deposited PLZT active layer on nickel mesh and MnO₂ counter electrode is depicted as FIG. 4 for an easy understanding of a variation of the process.

Charge a ball mill with 500 grams formulated PLZT ceramic powder (MRA Lab, US), 50 grams of UCAR Latex 820 emulsion (Dow Chemical, US), 2 liters of water, and 2 liters of milling ball media. Run the ball mill for 2 hours to obtain a PLZT suspension slip as an EPD bath solution.

A commercially available 50 μm thick nickel wire woven 180×180 mesh 41 with a 70% opening ratio and a surface area of 0.06 square meters per cubic centimeter is used as the coating substrate. The 180×180 mesh is defined as a weaving density of 180 wires per inch in each direction in the mesh plane. FIG. 4a shows a schematic view of the mesh cross section. In order to wind the mesh into a cylindrical format after coated with PLZT green ceramic layer, the mesh substrate 41 is pre-diced in a strip shape of 12 mm wide and 20 mm long. Immerse the mesh strip into the previously prepared PLZT suspension solution about 11.5 mm deep and leave 0.5 mm of the mesh above the liquid surface as the EPD cathode connected to a 24 volts DC bias source. A 60 μm thick PLZT ceramic layer 42 shown in FIG. 4b is deposited on the nickel mesh surface in 10 minutes and dried at 80° C. for 5 minutes. Thus obtained mesh with green ceramic coating is then wound on a 3 mm diameter core 44 into a cylindrical component body and baked at 350° C. for 24 hours. Followed by a sintering process at 1150° C. in a N₂/H₂ atmosphere, and further annealed under a partial oxygen pressure at 1000° C. to re-oxidize the PLZT ceramic layer into an insulating dielectric active layer, the PLZT ceramic layer between any two spirals of wound mesh will be sintered together at numerous contacting spots to become a one-piece capacitor component with connected PLZT ceramic channels among the mesh lattices throughout the cylindrical components body.

Furthermore, the sintered PLZT cylindrical component body will be impregnated with a MnNO₃ electrolytic solution and heated up to 550° C. to turn the MnNO₃ coating into a conductive MnO₂ layer covering the PLZT dielectric surface as a counter electrode 43 as shown in FIG. 4c and FIG. 4d.

Similar to the termination process described in process flow chart of FIG. 2 step 27a, dipping silver paste on the both ends of the cylindrical capacitor component to form terminals 45a and 45b which are electrically connected to the nickel mesh electrode 41 or MnO₂ counter electrode 43 respectively. The two electrode terminals need to be attached with lead wires 46 and packaged in a can case 47 to become a wire leaded capacitor component.

### Example 3

In addition to ceramic capacitors, the present invention can be applied to the manufacture of different type of electronic ceramic components including varistors or other electronic ceramic components with a structure of two electrodes sandwiched ceramic active layer. Example 3 demonstrates the process using the same basic technique for ceramic capacitors as described above to coat a ceramic material exhibiting a voltage dependent non-linear resistance, such as a zinc oxide, on a mesh substrate for a varistor application.

Charge a ball mill with 400 grams of pre-formulated ZnO powder, 24 grams of polyvinyl butyral resin flake (Sekisui, Japan), 198 grams toluene, 98 grams ethanol, and 1 liter of milling ball media. Run the ball mill for 2 hours to make a viscous ZnO slip. The same 180×180 nickel wire woven mesh as used in example 2, pre-diced in a size of 6.4 mm×1.6 mm (1206 case size with double length) is dipped in above prepared ZnO slip, and dried at 80° C. for 10 minutes to obtain a 20 μm thick green ZnO ceramic layer. Repeat the dipping and drying process five times to obtain a 100 μm thick coated ZnO green ceramic layer on the surface of the nickel mesh. After thermally decomposed at 350° C. for 24 hours, and sintered at 1300° C. for 3 hours under a nitrogen atmosphere, a 75 μm thick ZnO active layer is formed covering the nickel mesh electrode. A 0.5 μm thick nickel coating as the counter electrode is applied on the top of the ZnO surface through an electroless nickel plating process. Similar to example 1, at this stage each rectangular piece will be diced in the middle of the longitude side into two pieces of 1206 case size ZnO single layer varistor unit having an exposed nickel mesh electrode at one end. Both ends of the varistor component unit are then covered with a silver paste to form two terminals electrically connected to inner nickel mesh electrode and outer nickel plated counter electrode respectively. Plurality of said single layer varistor units can be stacked up, terminated, and sealed to become a multilayer varistor.

### Example 4

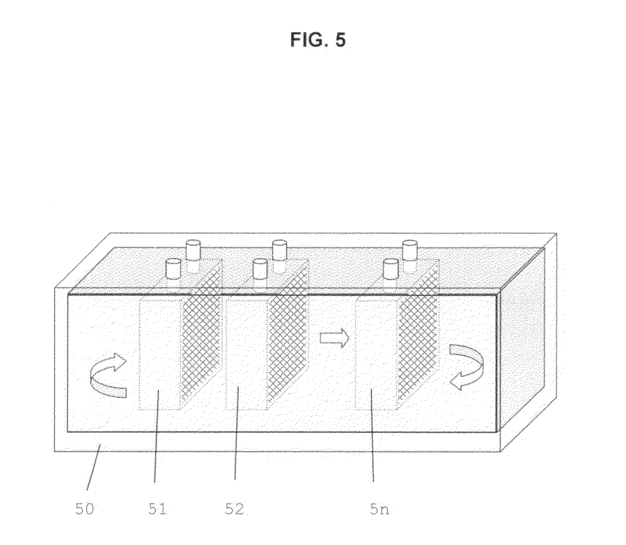

When working in a circuit, ceramic capacitors may heat themselves up because a portion of electrical energy is consumed by the capacitor dielectric losses. Precaution for overheating has to be taken, especially for large size capacitors connected to power lines. It is an advantage of this invention to cool the ceramic capacitors more efficiently by allowing liquid coolant or forced air passing through the open channels among the mesh lattices if a mesh with large open ratio is selected as the capacitor mesh electrode. As shown in FIG. 5, multiple ceramic capacitors 51 to 5n made in accordance with the method described above with naked (terminated but not packed with protective sealing) sandwiched structure are assembled in a package 50 with cooling means of circulated coolant. The capacitors 51 to 5n can be connected either in parallel or in series to have a multiplied capacitance or multiplied working voltage accordingly.

As a result, the scope of the present invention extends to a variety of materials, methods of fabrication, and processing techniques which are employed to manufacture electronic ceramic components with a functional structure of two electrodes sandwiched ceramic active layer in the principle of coating ceramic active layer on a conductive mesh as disclosed above.

What is claimed is:

1. A method for making an electronic ceramic component comprising:
A conductive mesh electrode consisting of at least one sheet of electrically conductive mesh substrate.
A ceramic active layer formed by coating at least one ceramic precursor on the surface of said conductive mesh electrode by chemical coating methods.
A layer of electrically conductive material formed on the surface of said ceramic active layer as a counter electrode.

2. An electronic ceramic component as defined in claim 1, wherein the ceramic precursor coated mesh electrode is wound or stacked, which is further sintered into a multilayer ceramic component body with interconnected ceramic channels to allow impregnation of at least one conductive substance into said multilayer ceramic component body as a counter electrode of said electronic ceramic component.

3. An electronic ceramic component as defined in claim 1, wherein the ceramic precursor coated mesh electrode is sintered and further coated with at least one layer of conductive material as a counter electrode to form a single layer electronic ceramic component.

4. A single layer ceramic component as defined in claim 3, wherein plurality of said single layer electronic ceramic components are stacked and terminated into a multilayer electronic ceramic component.

5. An electronic ceramic component as defined in claim 1, wherein said ceramic active layer is formed by coating at least one ceramic precursor through chemical methods selected from sol gel process, coprecipitation process, electrophoretic deposition process, metal-organic chemical vapor deposition process, or ceramic slip process.

6. An electronic ceramic component as defined in claim 1, wherein said electrically conductive mesh substrate has a shape of reticulated lattice with plurality openings made through process selected from wire weaving, electrochemical plating or etching, mechanical stretching or punching, particles sintering, or the combination of more than one process listed above.

7. An electronic ceramic component as defined in claim 1, wherein said conductive mesh electrode and conductive counter electrode are made from at least one of electrically conductive substance which has an electrical resistivity less than 10² Ohm-cm such as conductive polymers, semiconductors selected from carbon, graphite, and metal oxides, or transition metals selected from silver, palladium, platinum, gold, nickel, manganese, tungsten, copper, titanium, and zinc, or the alloy of at least two of above listed metals.

8. An electronic ceramic component as defined in claim 1, wherein said counter electrode is deposited by chemical methods selected from sol gel process, hydrothermal process, coprecipitation process, electrophoretic deposition process, and metal-organic chemical vapor deposit process, or physical methods selected from vacuum deposition, plasma sputtering, Ion beam deposition, and laser ablation.

9. An electronic ceramic component as defined in claim 1, wherein said counter electrode is either a wet electrode able to penetrate into the interconnected ceramic channels among wound or stacked mesh lattices formed by impregnating electrolytic solutions, conductive oxide precursors, or liquid conductive polymers, or a dry electrode formed by heat treatment of above listed wet electrodes.

10. A ceramic capacitor comprising:
A conductive mesh electrode consisting of at least one sheet of electrically conductive mesh substrate.
A ceramic dielectric layer formed by coating at least one ceramic precursor on the surface of said conductive mesh electrode by chemical coating methods.
A layer of electrically conductive material formed on the surface of said ceramic dielectric layer as a counter electrode.

11. A ceramic capacitor as defined in claim 10, wherein the ceramic precursor coated mesh substrate is wound or stacked, which is further sintered into a multilayer ceramic body with interconnected ceramic channels among the mesh lattices to allow impregnation of conductive substance into the multilayer ceramic body as a counter electrode of said multilayer ceramic capacitor.

12. A ceramic capacitor as defined in claim 10, wherein the ceramic precursor coated mesh electrode is sintered and then further coated with at least one layer of conductive material as a counter electrode to form a single layer ceramic capacitor.

13. A single layer ceramic capacitor as defined in claim 12, wherein more than one said single layer ceramic capacitor is stacked and terminated into a multilayer ceramic capacitor.

14. A ceramic capacitor as defined in claim 10, wherein said ceramic dielectric layer is formed by coating at least one ceramic precursor through chemical methods selected from sol gel process, coprecipitation process, electrophoretic deposition process, metal-organic chemical vapor deposition process, or ceramic slip process.

15. A ceramic capacitor as defined in claim 10, wherein said ceramic dielectric layer contains ceramic dopands and glass frits like those based on bismuth oxide, cuprate oxide, calcium oxide, boron oxide, lithium oxide or the combination of more than one of above listed, which can be formulated directly into the ceramic precursor, or be used as partial precursor of the ceramic formulation, or be coated as an extra layer to the conductive mesh substrate.

16. A ceramic capacitor as defined in claim 10, wherein said conductive mesh has a shape of reticulated lattice with plurality openings made through a process selected from wire weaving, electrochemical plating or etching, mechanical stretching or punching, particles sintering, or the combination of more than one process above listed.

17. A ceramic capacitor as defined in claim 10, wherein said conductive mesh electrode and conductive counter electrode are made from at least one of electrically conductive substances which have an electrical resistivity less than 10² Ohm-cm such as semiconductors, conductive polymers, or transition metals selected from noble metal group of silver, palladium, platinum, and gold, or base metal group of nickel, manganese, tungsten, copper, titanium, and zinc, or the alloy of at least two of above listed metals.

18. A ceramic capacitor as defined in claim 10, wherein said conductive counter electrode is deposited by chemical methods selected from sol gel process, hydrothermal process, coprecipitation process, electrophoretic deposition process, metal-organic chemical vapor deposit process, and ceramic slip process, or by physical process selected from vacuum deposition, plasma sputtering, ion beam deposition, or laser ablation, or by impregnating electrolytic substances, conductive oxide precursors, or conductive polymers, or other electrically conductive substance in its liquid form to be able to penetrate into the connected dielectric channels among wound or stacked mesh lattices.

19. A ceramic capacitor as defined in claim 10, wherein said ceramic dielectric layer is made from dielectric formulations selected from titanate oxide, barium titanate, strontium titanate, calcium titanate, lead titanate, magnesium titanate, calcium zirconate, barium zirconate , strontium zirconate, lead zirconate titanate, lead lanthanum zirconate titanate, lead niobium zirconate titanate, lead magnesium niobate, and the solid solution of more than one of above listed.

20. A ceramic capacitor assembly consisting of plurality of ceramic capacitors defined in claim 10 which are packed in a container filled with liquid coolant or equipped with air circulation so that said ceramic capacitors are kept from overheating by the circulation of the coolant or air passing through the open channels among the mesh lattices of said ceramic capacitors.
